(19) United States
(12) Patent Application Publication
(10) Pub. No.: US 2026/0101532 A1
(43) Pub. Date: Apr. 9, 2026

(54) NITRIDE-BASED SEMICONDUCTOR DEVICE

(71) Applicant: Sanken Electric Co., Ltd., Saitama-ken (JP)

(72) Inventor: Ken Sato, Saitama-ken (JP)

(73) Assignee: Sanken Electric Co., Ltd., Saitama-ken (JP)

(21) Appl. No.: 19/348,802

(22) Filed: Oct. 3, 2025

(30) Foreign Application Priority Data
May 29, 2025 (JP) 2025-090223
Oct. 8, 2024 (JP) 2024-176811

(51) Int. Cl. H10D 30/47; H10D 62/10; H10D 62/824; H10D 64/00

(52) U.S. Cl. CPC H10D 30/475; H10D 62/102; H10D 62/126; H10D 62/824; H10D 64/112

(57) ABSTRACT

A nitride-based semiconductor device includes a third nitride-based semiconductor layer having a two-dimensional hole gas layer. As viewed from a control electrode side, the third nitride-based semiconductor layer on a first main electrode side includes a recess, or includes multiple third nitride-based semiconductor layers intermittently provided on a second nitride-based semiconductor layer and each of the multiple third nitride-based semiconductor layers is electrically connected to the control electrode.

### CROSS-REFERENCE TO RELATED APPLICATION

This application claims the priority benefit of Japan application serial no. 2024-176811, filed on October 8, 2024, and Japan application serial no. 2025-090223, filed on May 29, 2025. The entirety of the above-mentioned patent applications is hereby incorporated by reference herein and made a part of this specification.

### BACKGROUND

### Technical Field

The disclosure relates to a structure of a nitride-based semiconductor device using a heterojunction of nitride-based semiconductors.

### Related Art

Semiconductor devices using a heterojunction of nitride-based semiconductors (GaN and mixed crystal semiconductors thereof) include, for example, a high electron mobility transistor (HEMT). Such semiconductor devices require a breakdown voltage between the source and the drain in the OFF state. In addition, the current collapse phenomenon is observed in the HEMT using nitride-based semiconductors, and mitigation of local electric field concentration between the drain and the gate is said to be effective for reducing the current collapse phenomenon.

As an example of a HEMT structure using nitride-based semiconductors, for example, a HEMT structure using a polarization super junction (PSJ) structure as described in Patent Document 1 (Japanese Patent Application Laid-Open No. 2023-123161) is known. FIG. 14 is a cross-sectional view schematically showing a HEMT structure including a PSJ structure, and FIG. 15 is a plan view schematically showing a HEMT structure including a PSJ structure. In a nitride-based semiconductor device 100 shown in FIG. 14, on a nitride-based semiconductor layer (first nitride-based semiconductor layer 3) composed of, for example, undoped GaN, a nitride-based semiconductor layer (second nitride-based semiconductor layer 4) composed of undoped AlGaN (specifically, Al₁₋ₓGaₓN: 0 < x < 1) having a band gap energy larger than the first nitride-based semiconductor layer 3 (GaN) is formed. Accordingly, a two-dimensional electron gas layer is formed in the first nitride-based semiconductor layer 3 in the vicinity of the interface between the first nitride-based semiconductor layer 3 and the second nitride-based semiconductor layer 4.

On the second nitride-based semiconductor layer 4, a nitride-based semiconductor layer (third nitride-based semiconductor layer 8) composed of undoped GaN similar to the first nitride-based semiconductor layer 3 is formed. In the third nitride-based semiconductor layer 8 in the vicinity of the interface between the second nitride-based semiconductor layer 4 and the third nitride-based semiconductor layer 8, a two-dimensional hole gas in which holes are accumulated in a planar configuration is formed.

By setting a gate electrode 7, which is provided on the third nitride-based semiconductor layer 8 via a P-type semiconductor layer 9, to a negative potential, the two-dimensional electron gas directly below the gate electrode 7 disappears, and the nitride-based semiconductor device 100 turns into the OFF state. During turn-off, electrons constituting the two-dimensional electron gas move to the drain electrode 6 side, and holes constituting the two-dimensional hole gas move toward the gate electrode 7 side. Accordingly, the electric field strength in the third nitride-based semiconductor layer 8 extending from the gate electrode 7 toward the drain electrode 6 is configured to be approximately uniform, and a local increase in electric field strength directly below the gate electrode 7 and the like is reduced. Thus, an increase in breakdown voltage can be realized, and the current collapse phenomenon can be reduced.

In the region provided with the PSJ structure, the electric field strength can be configured to be approximately uniform to increase the breakdown voltage. However, with the PSJ structure provided, when the nitride-based semiconductor device is in the ON state, the concentration of the two-dimensional electron gas decreases, the operating resistance value increases, and the allowable current value decreases.

### SUMMARY

A nitride-based semiconductor device of an embodiment of the disclosure includes: a first nitride-based semiconductor layer having a two-dimensional electron gas layer at an upper part; a second nitride-based semiconductor layer provided on the first nitride-based semiconductor layer and having a band gap energy larger than a band gap energy of the first nitride-based semiconductor layer; a third nitride-based semiconductor layer provided on the second nitride-based semiconductor layer, composed of a nitride-based semiconductor material having a band gap energy smaller than the band gap energy of the second nitride-based semiconductor layer, and having a two-dimensional hole gas layer formed in the vicinity of an interface with the second nitride-based semiconductor layer; a P-type semiconductor layer on the third nitride-based semiconductor layer; a first main electrode on a high potential side electrically connected to the two-dimensional electron gas layer; a second main electrode on a low potential side electrically connected to the two-dimensional electron gas layer; and a control electrode located between the first main electrode and the second main electrode and electrically connected to the P-type semiconductor layer. As viewed from the control electrode side, the third nitride-based semiconductor layer on the first main electrode side includes a recess, or includes multiple third nitride-based semiconductor layers intermittently provided on the second nitride-based semiconductor layer and each of the multiple third nitride-based semiconductor layers is electrically connected to the control electrode.

Further, a nitride-based semiconductor device of an embodiment of the disclosure includes: a first nitride-based semiconductor layer having a two-dimensional electron gas layer at an upper part; a second nitride-based semiconductor layer provided on the first nitride-based semiconductor layer and having a band gap energy larger than a band gap energy of the first nitride-based semiconductor layer; a third nitride-based semiconductor layer provided on the second nitride-based semiconductor layer, composed of a nitride-based semiconductor material having a band gap energy smaller than the band gap energy of the second nitride-based semiconductor layer, and having a first two-dimensional hole gas layer formed in the vicinity of an interface with the second nitride-based semiconductor layer; a P-type semiconductor layer on the third nitride-based semiconductor layer; a first main electrode on a high potential side electrically connected to the two-dimensional electron gas layer; a second main electrode on a low potential side electrically connected to the two-dimensional electron gas layer; and a control electrode located between the first main electrode and the second main electrode and electrically connected to the P-type semiconductor layer. In a plan view, in a region formed by extending a length of the third nitride-based semiconductor layer that ranges from an end closest to the first main electrode side to directly below the control electrode, by a length of the control electrode in an extending direction of the control electrode, there is a region where a two-dimensional hole gas is not formed or has a low concentration.

Since an embodiment of the disclosure is configured as described above, it is possible to provide a nitride-based semiconductor device that reduces the operating resistance value while configuring the electric field strength to be approximately uniform to increase the breakdown voltage.

### BRIEF DESCRIPTION OF THE DRAWINGS

FIG. 1 is a cross-sectional view showing a structure of a first embodiment of a nitride-based semiconductor device according to an embodiment of the disclosure.

FIG. 2 is a plan view showing the structure of the first embodiment of the nitride-based semiconductor device according to an embodiment of the disclosure.

FIG. 3 is a plan view showing a structure of a second embodiment of the nitride-based semiconductor device according to an embodiment of the disclosure.

FIG. 4 is a plan view showing a structure of a third embodiment of the nitride-based semiconductor device according to an embodiment of the disclosure.

FIG. 5 is a plan view showing a structure of a fourth embodiment of the nitride-based semiconductor device according to an embodiment of the disclosure.

FIG. 6 is a plan view showing a structure of a fifth embodiment of the nitride-based semiconductor device according to an embodiment of the disclosure.

FIG. 7 is a plan view showing a structure of a modification example of the fifth embodiment of the nitride-based semiconductor device according to an embodiment of the disclosure.

FIG. 8 is a cross-sectional view showing a structure of a sixth embodiment of the nitride-based semiconductor device according to an embodiment of the disclosure.

FIG. 9 is a plan view showing the structure of the sixth embodiment of the nitride-based semiconductor device according to an embodiment of the disclosure.

FIG. 10 is a cross-sectional view showing a structure of a seventh embodiment of the nitride-based semiconductor device according to an embodiment of the disclosure.

FIG. 11 is a plan view showing the structure of the seventh embodiment of the nitride-based semiconductor device according to an embodiment of the disclosure.

FIG. 12 is a cross-sectional view showing a structure of an eighth embodiment of the nitride-based semiconductor device according to an embodiment of the disclosure.

FIG. 13 is a plan view showing the structure of the eighth embodiment of the nitride-based semiconductor device according to an embodiment of the disclosure.

FIG. 14 is a cross-sectional view showing a structure of a conventional nitride-based semiconductor device with a PSJ structure.

FIG. 15 is a plan view showing a structure of a conventional nitride-based semiconductor device with a PSJ structure.

### DESCRIPTION OF THE EMBODIMENTS

Hereinafter, nitride-based semiconductor devices according to embodiments of the disclosure will be described with reference to the drawings. In the following description of the drawings, the same or similar portions will be labeled with the same or similar reference signs. However, it should be noted that the drawings are schematic, and the relationship between thickness and planar dimensions, the ratio of lengths of respective parts, etc., differ from actual ones. Thus, specific dimensions should be determined by taking the following description into consideration. Obviously, portions having dimensional relationships and ratios that differ between the drawings may be included.

In addition, the embodiments shown below exemplify nitride-based semiconductor devices for embodying the technical concept of the disclosure, and the technical concept of the disclosure does not specify the shapes, structures, arrangements, etc., of components to those described below. The embodiments of the disclosure may be variously modified within the scope of the claims. In the disclosure, terms specifying up and down directions such as “on” and “below” are used for convenience of description, and if a constituent element is substantially the same as the constituent element of the disclosure, even in the case of being provided on a lateral surface, such a constituent element belongs to the scope of rights of the present invention.

In addition, the term “on” includes not only the case of being formed in contact with a particular target, but also the case of being formed with another layer interposed therebetween. In addition, in the disclosure, the term “connection” is not limited to direct connection, and if a constituent element is substantially the same as the constituent element of the disclosure, even in the case of connection with a resistor or the like interposed therebetween, such a constituent element belongs to the scope of rights of the present invention.

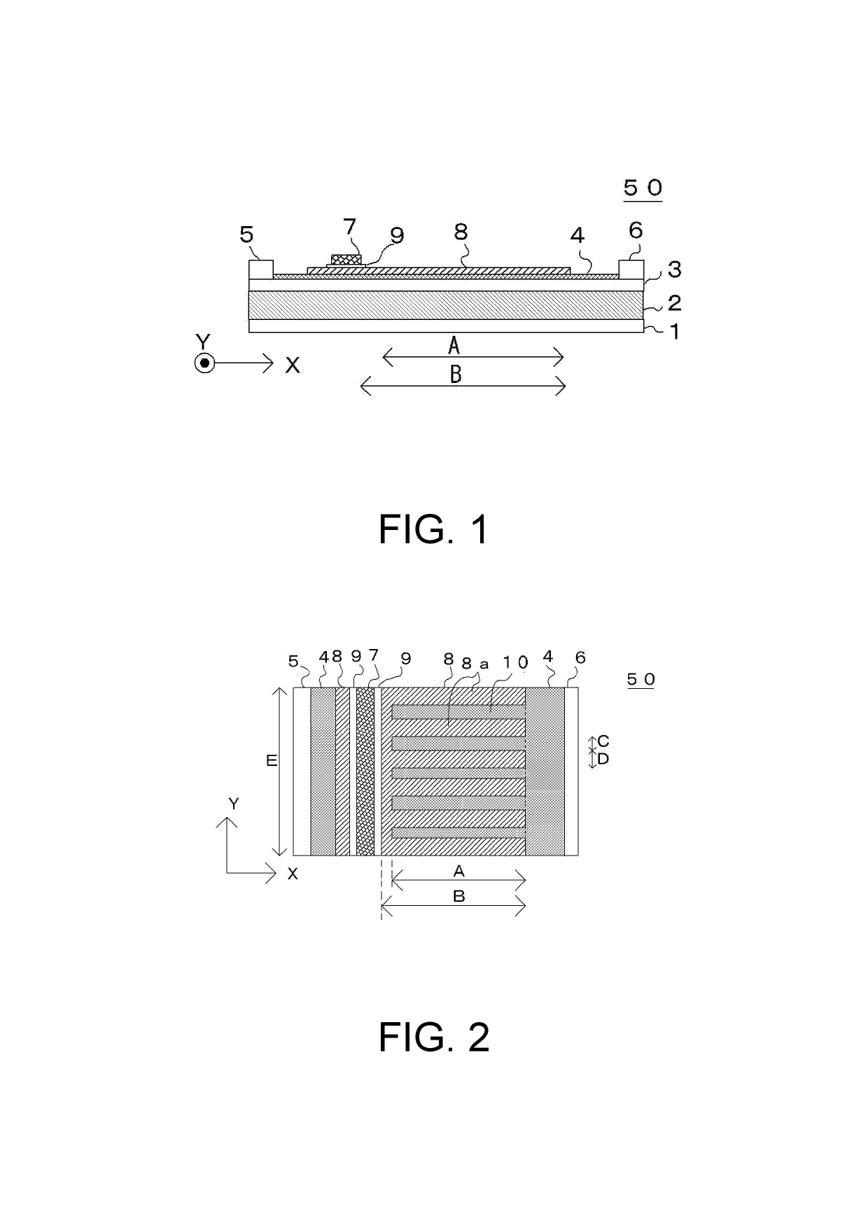

As shown in a cross-sectional view of a nitride-based semiconductor device 50 in FIG. 1, the nitride-based semiconductor device 50 according to an embodiment of the disclosure includes: a substrate 1 composed of sapphire, GaN, silicon, or silicon carbide; a buffer layer 2 provided on the substrate 1 and having a multilayer buffer with repeated stacking of AlN or AlₓGa₁₋ₓN and Al_{y}Ga_{1-Y}N, or an AlₓGa₁₋ₓN structure with a gradient in Al composition; a first nitride-based semiconductor layer 3 provided on the buffer layer 2 and composed of undoped GaN; a second nitride-based semiconductor layer 4 provided on the first nitride-based semiconductor layer 3 and composed of undoped Al_{Z}Ga_{1-Z}N (where Z > 0) containing Al, for example, having a band gap energy larger than the first nitride-based semiconductor layer 3; and a third nitride-based semiconductor layer 8 provided on the second nitride-based semiconductor layer 4 and composed of undoped GaN, for example, having a band gap energy smaller than the second nitride-based semiconductor layer 4.

In the first nitride-based semiconductor layer 3 in the vicinity of the interface between the first nitride-based semiconductor layer 3 and the second nitride-based semiconductor layer 4, a two-dimensional electron gas layer is formed by spontaneous polarization, piezoelectric polarization, or both spontaneous polarization and piezoelectric polarization. In addition, in the third nitride-based semiconductor layer 8 in the vicinity of the interface between the second nitride-based semiconductor layer 4 and the third nitride-based semiconductor layer 8, a two-dimensional hole gas layer is formed by spontaneous polarization, piezoelectric polarization, or both spontaneous polarization and piezoelectric polarization.

A source electrode 5 and a drain electrode 6 are formed on the first nitride-based semiconductor layer 3 or on the second nitride-based semiconductor layer 4, and are composed of a material that forms ohmic connection with the two-dimensional electron gas layer, e.g., composed of a stacked structure of Ti/Au or the like. The drain electrode 6 and the source electrode 5 are not in contact with the third nitride-based semiconductor layer 8, and are not connected to the two-dimensional hole gas layer in the third nitride-based semiconductor layer 8, either.

A gate electrode 7 electrically connected to the third nitride-based semiconductor layer 8 is provided on the second nitride-based semiconductor layer 4 between the source electrode 5 and the drain electrode 6. Herein, on the second nitride-based semiconductor layer 4 in FIG. 1, the third nitride-based semiconductor layer 8, a P-type semiconductor layer 9 composed of p-GaN or NiO, for example, on the third nitride-based semiconductor layer 8, and the gate electrode 7 on the P-type semiconductor layer 9 are formed. The gate electrode 7 is composed of a material that forms relative ohmic contact with the P-type semiconductor layer 9, e.g., composed of a stacked structure of Ni/Au or the like.

The portion of the third nitride-based semiconductor layer 8 (the portion with a length B in FIG. 2) that extends to the drain electrode 6 side beyond the gate electrode 7 or the P-type semiconductor layer 9 is sometimes called a polarization super junction (PSJ) structure.

Herein, within the range enclosed by the length B of the PSJ structure (in FIG. 2, the boundary on the drain electrode 6 side of this range is indicated by a dotted line), multiple recesses (grooves) 10 having a length A extending from the drain electrode 6 side to the gate electrode 7 side are provided in a direction (Y-direction in FIG. 2) in which the gate electrode 7 extends. As viewed from the gate electrode 7 closest to the source electrode 5 side, within the range enclosed by the length B of the PSJ structure, multiple recesses (grooves) 10 having a length A from the drain electrode 6 side to the gate electrode 7 side (X-direction in FIG. 2) are provided in the Y-direction in FIG. 2. Within the range enclosed by the length A in FIG. 2, a portion 8a where the portion of the PSJ structure of the third nitride-based semiconductor layer 8 is provided and the recess (groove) 10 are alternately and repeatedly formed in the Y-direction.

The recess (groove) 10 is a region where at least a part of the third nitride-based semiconductor layer 8 is not provided, and is a region where a two-dimensional hole gas layer is not formed or a region where the two-dimensional hole gas layer is minimal. The recess (groove) 10 is, for example, a portion where a groove or a hole that does not penetrate through the third nitride-based semiconductor layer 8 is formed, or a portion where a groove or a hole that penetrates through the third nitride-based semiconductor layer 8 is provided. In the recess (groove) 10, at least a part of the thickness of the third nitride-based semiconductor layer 8 may remain, and the recess (groove) 10 may be a region where a two-dimensional hole gas layer is not formed or a region where the concentration of the two-dimensional hole gas layer is low. In this case, occurrence of crystal defects or the like in an upper part of the second nitride-based semiconductor layer 4 directly below the recess (groove) 10 can be suppressed, and characteristics such as current collapse and ON-resistance can be improved.

The P-type semiconductor layer 9 and the gate electrode 7 are provided on the second nitride-based semiconductor layer 4 on the source electrode 5 side of the third nitride-based semiconductor layer 8, and the P-type semiconductor layer 9 and the third nitride-based semiconductor layer 8 may be electrically connected to each other. In addition, as shown in FIG. 1, the P-type semiconductor layer 9 and the gate electrode 7 may be stacked on the third nitride-based semiconductor layer 8.

In addition, within the range of a maximum length Bₘₐₓ of the PSJ structure, the area in which the two-dimensional hole gas layer is formed in the third nitride-based semiconductor layer 8 may be smaller than the area (E × Bₘₐₓ) of a range enclosed and defined with respect to a length (finger length of the gate electrode 7) E of the gate electrode 7 in the direction (Y-direction in FIG. 2) in which the gate electrode 7 extends, or there may be a region where the hole concentration of the two-dimensional hole gas layer is low.

Upon applying a potential equal to or greater than a threshold value to the gate electrode 7, the depletion layer directly below the gate electrode 7 decreases, the two-dimensional electron gas layer becomes conductive, and the nitride-based semiconductor device 50 is turned on. At this time, a two-dimensional hole gas layer is formed in the third nitride-based semiconductor layer 8, canceling out electrons trapped at the surface of the second nitride-based semiconductor layer 4 directly below and in the vicinity of the third nitride-based semiconductor layer 8. Accordingly, the current collapse phenomenon of the nitride-based semiconductor device 50 can be reduced.

Herein, the concentration of the two-dimensional electron gas layer directly below the portion 8a where the portion of the PSJ structure is provided decreases to some extent. However, in the nitride-based semiconductor device 50, two-dimensional hole gas in the recess (groove) 10 is not present or is less than in the portion 8a where the PSJ structure is provided. Thus, the concentration of the two-dimensional electron gas layer directly below the recess (groove) 10 can be relatively increased. As a result, the ON-resistance of the nitride-based semiconductor device 50 can be reduced.

On the other hand, upon applying an OFF signal (e.g., a negative potential) to the gate electrode 7, carriers in the two-dimensional electron gas layer directly below the gate electrode 7 are depleted, and the nitride-based semiconductor device 50 is turned off. Holes in the two-dimensional hole gas layer in the third nitride-based semiconductor layer 8 move toward the gate electrode 7 and are discharged, and the concentration of the two-dimensional hole gas layer in the third nitride-based semiconductor layer 8 decreases. Accordingly, the electric field strength in the second nitride-based semiconductor layer 4 below the third nitride-based semiconductor layer 8 is configured to be approximately uniform in a direction (X-direction in FIG. 2) from the gate electrode 7 to the drain electrode 6. Thus, local increase in electric field strength in the vicinity directly below the gate electrode 7 and the like can be suppressed, and the breakdown voltage of the nitride-based semiconductor device can be increased.

In the OFF state of the nitride-based semiconductor device 50, under the influence of the electric field strength in the third nitride-based semiconductor layer 8, the electric field at the surface of the second nitride-based semiconductor layer 4 directly below the portion 8a where the PSJ structure is provided is configured to be approximately uniform. The recess (groove) 10 is sandwiched between regions of the second nitride-based semiconductor layer 4 directly below the portion 8a where the PSJ structure is provided in the Y-direction of FIG. 2, for example. Although the electric field strength at the surface of the recess (groove) 10 forms a valley, under the influence of the electric field of the portion where the PSJ structure is provided, the electric field strength at the surface of the recess (groove) 10 is lifted up and becomes relatively gentle. Thus, the nitride-based semiconductor device 50 can suppress electrons trapped at the surface of the second nitride-based semiconductor layer 4 and the like, and reduce the current collapse phenomenon.

Based on the above, it is possible to provide a nitride-based semiconductor device 50 that reduces ON-resistance while configuring the electric field strength to be approximately uniform to increase the breakdown voltage.

Within the range of the length B of the PSJ structure in FIG. 2, the recess (groove) 10 may be provided closer to the drain electrode 6 side compared to the gate electrode 7 side. Accordingly, while mitigating electric field concentration on the gate electrode 7 side with the PSJ structure, the concentration of the two-dimensional electron gas layer can be increased directly below the recess (groove) 10 on the drain electrode 6 side where the PSJ structure is not provided, and an increase in ON-resistance can be suppressed. For example, in the direction (X-direction in FIG. 2) in which the PSJ structure extends, taking the maximum length Bₘₐₓ of the PSJ structure and the length A of the region where the recess (groove) 10 is provided, A/Bₘₐₓ may be, for example, greater than 1/3 and smaller than 1. In addition, taking the width (length in the Y-direction in FIG. 2) of the recess (groove) 10 as C and the width (length in the Y-direction in FIG. 2) of the portion where the PSJ structure extends as D, the width D may be configured to be larger than the width C. Accordingly, it is possible to provide a nitride-based semiconductor device 50 that reduces ON-resistance while configuring the electric field strength to be approximately uniform to increase the breakdown voltage.

### Second Embodiment

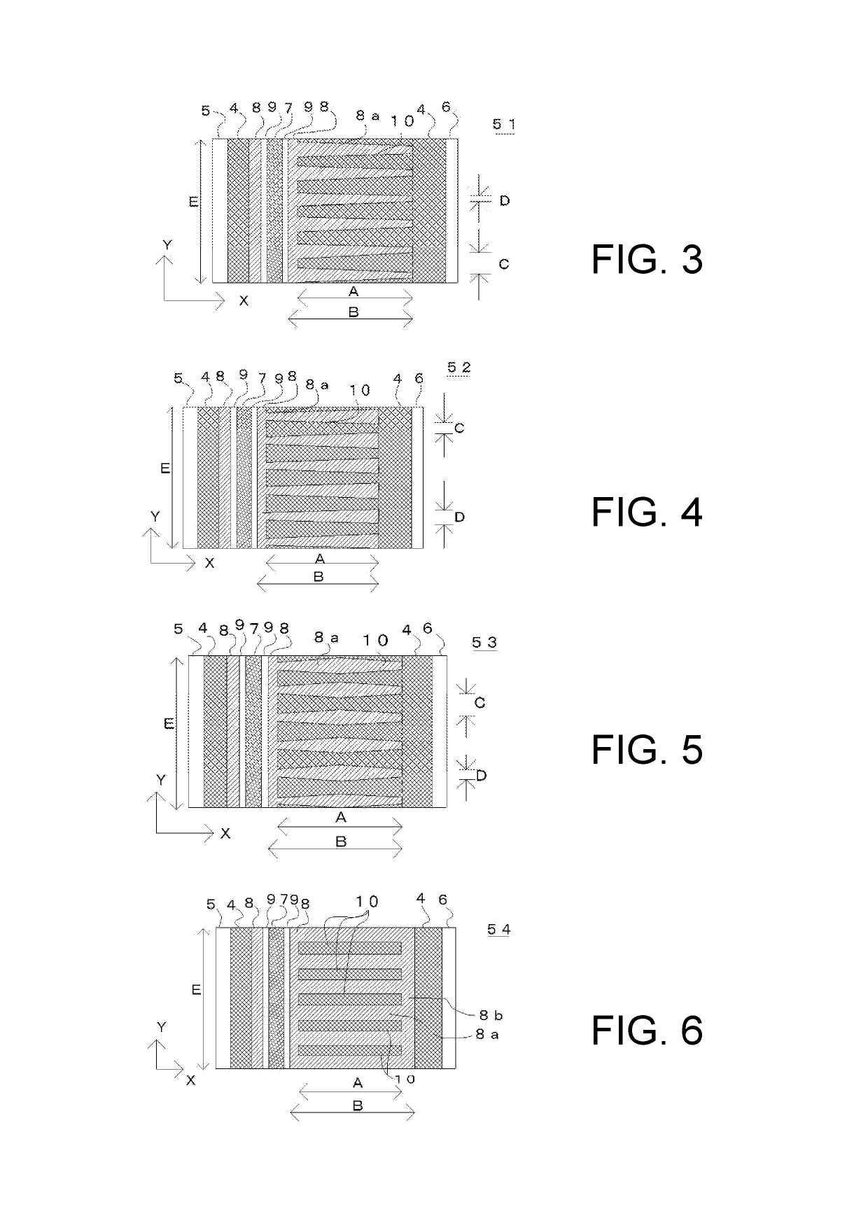

FIG. 3 is a plan view showing a second embodiment of a nitride-based semiconductor device 51 of the disclosure. Although not particularly limited, as shown in the plan view of FIG. 3, the recess (groove) 10 is provided in the third nitride-based semiconductor layer 8 from the drain electrode 6 side toward the gate electrode 7 side. The width (width D in the Y-direction in FIG. 3) of the portion 8a where the PSJ structure of the third nitride-based semiconductor layer 8 extends becomes narrower from the gate electrode 7 side toward the drain electrode 6 side (X-direction in FIG. 3). The groove width (width C in the Y-direction in FIG. 3) of the recess (groove) 10 becomes wider from the gate electrode 7 side toward the drain electrode 6 side (X-direction in FIG. 3).

In the nitride-based semiconductor device 51 as well, within the range enclosed by the maximum length Bₘₐₓ of the PSJ structure (in FIG. 3, the boundary on the drain electrode 6 side of this range is indicated by a dotted line), multiple recesses (grooves) 10 having a length A extending from the drain electrode 6 side to the gate electrode 7 side are provided in a direction (Y-direction in FIG. 3) in which the gate electrode 7 extends.

In addition, within the range of the maximum length Bₘₐₓ of the PSJ structure, the area in which the two-dimensional hole gas layer is formed in the third nitride-based semiconductor layer 8 may be smaller than the area (E × Bₘₐₓ) of a range enclosed and defined with respect to a length (finger length of the gate electrode 7) E of the gate electrode 7 in the direction (Y-direction in FIG. 3) in which the gate electrode 7 extends, or there may be a region where the hole concentration of the two-dimensional hole gas layer is low.

Thus, in the nitride-based semiconductor device 51 of the second embodiment as well, it is possible to provide a nitride-based semiconductor device that suppresses an increase in ON-resistance while reducing the current collapse phenomenon. In addition, in FIG. 3, a ratio (width C / width C + width D) on the drain electrode 6 side of the portion where the PSJ structure does not extend is larger than the ratio (width C / width C + width D) on the gate electrode 7 side, and for example, the ratio on the drain electrode 6 side is larger than in the case of the semiconductor device of the first embodiment. Thus, the nitride-based semiconductor device 51 can reduce ON-resistance further. In FIG. 3, a ratio (width D / width C + width D) on the gate electrode 7 side of the portion 8a where the PSJ structure extends is larger than the ratio (width D / width C + width D) on the drain electrode 6 side, and for example, the ratio on the gate electrode 7 side is larger than in the case of the semiconductor device of the first embodiment. Accordingly, the two-dimensional electron gas layer directly below the gate electrode 7 side is easily depleted, and the electric field distribution in the Y-direction can be configured to be more uniform. The end of the PSJ structure on the drain electrode 6 side is narrower than the portion of the PSJ structure on the gate electrode 7 side, and electric field concentration directly below the end part of the gate electrode 7 is mitigated.

Based on the above, it is possible to provide a nitride-based semiconductor device 51 that reduces ON-resistance further while configuring the electric field strength to be approximately uniform to increase the breakdown voltage.

### Third Embodiment

FIG. 4 is a plan view showing a third embodiment of a nitride-based semiconductor device 52 of the disclosure. Although not particularly limited, as shown in the plan view of FIG. 4, recesses (grooves) 10 are provided from the drain electrode 6 side toward the gate electrode 7 side. Due to the groove of the recess (groove) 10, the width (width D in the Y-direction in FIG. 4) of the portion 8a where the PSJ structure extends becomes wider from the gate electrode 7 side toward the drain electrode 6 side (X-direction in FIG. 4). On the other hand, the width (width C in the Y-direction in FIG. 4) of the recess (groove) 10 becomes narrower from the gate electrode 7 side toward the drain electrode 6 side (X-direction in FIG. 4).

In the nitride-based semiconductor device 52 of the third embodiment as well, it is possible to provide a nitride-based semiconductor device that suppresses an increase in ON-resistance while reducing the current collapse phenomenon. In addition, within the range of a length A in FIG. 4, a ratio (width C / width C + width D) of the portion where the PSJ structure does not extend on the gate electrode 7 side is larger than the ratio (width C / width C + width D) on the drain electrode 6 side, and for example, the ratio on the gate electrode 7 side is larger than the ratio on the gate electrode 7 side in the nitride-based semiconductor device 50 of the first embodiment. Thus, the nitride-based semiconductor device 52 can increase the concentration of the two-dimensional electron gas layer on the gate electrode 7 side. In addition, within the range of the length A in FIG. 4, on the drain electrode 6 side, a ratio (width D / width C + width D) of the portion 8a where the PSJ structure extends is large, and is larger than, for example, the ratio (width D / width C + width D) on the drain electrode 6 side in the nitride-based semiconductor device 50 of the first embodiment. Thus, it is possible to provide a nitride-based semiconductor device 52 that reduces ON-resistance while configuring the electric field strength to be further approximately uniform to increase the breakdown voltage.

### Fourth Embodiment

FIG. 5 is a plan view showing a fourth embodiment of a nitride-based semiconductor device 53 of the disclosure. Although not particularly limited, as shown in the plan view of FIG. 5, recesses (grooves) 10 are provided in the third nitride-based semiconductor layer 8 from the drain electrode 6 side toward the gate electrode 7 side. Accordingly, on the gate electrode 7 side, the width (width D in FIG. 5) of the portion 8a where the PSJ structure extends becomes narrower toward the gate electrode 7. In addition, the width (width C in FIG. 5) of the recess (groove) 10 becomes wider toward the gate electrode 7.

On the other hand, on the drain electrode 6 side, the width (width D in FIG. 5) of the portion 8a where the PSJ structure extends becomes narrower toward the drain electrode 6, and the width (width C in FIG. 5) of the recess (groove) 10 becomes wider.

In other words, midway from the drain electrode 6 side toward the gate electrode 7 side, the width (width D in FIG. 5) of the portion 8a where the PSJ structure extends becomes widest, and the recess (groove) 10 becomes narrowest at the corresponding portion (the portion sandwiched by the widest portions 8a). Then, toward the drain electrode 6 side and the gate electrode 7 side, the width (width D in FIG. 5) of the portion 8a where the PSJ structure extends becomes narrower, and the width (width C in FIG. 5) of the recess (groove) 10 becomes wider.

In the nitride-based semiconductor device 53 as well, within the range enclosed by the maximum length Bₘₐₓ of the PSJ structure (in FIG. 5, the boundary on the drain electrode 6 side of this range is indicated by a dotted line), multiple recesses (grooves) 10 having a length A extending from the drain electrode 6 side to the gate electrode 7 side are provided in a direction (Y-direction in FIG. 5) in which the gate electrode 7 extends. In addition, within the range of the maximum length Bₘₐₓ of the PSJ structure, the area in which a two-dimensional hole gas layer is formed in the third nitride-based semiconductor layer 8 may be smaller than the area (E × Bₘₐₓ) of a range enclosed and defined with respect to a length (finger length of the gate electrode 7) E of the gate electrode 7 in the direction (Y-direction in FIG. 5) in which the gate electrode 7 extends, or there may be a region where the hole concentration of the two-dimensional hole gas layer is low.

The recess (groove) 10 is formed by etching the third nitride-based semiconductor layer 8. Thus, variation among products is likely to occur in the ratio between the recess (groove) 10 and the portion 8a of the PSJ structure. Since the depletion layer spreads from the gate electrode 7 side, this variation tends to lead to variation in breakdown voltage and variation in ON-resistance. Thus, the width D of the portion 8a of the PSJ structure is gradually increased toward midway of the portion 8a of the PSJ structure extending from the gate electrode 7 side to the drain electrode 6 side. Accordingly, the depletion layer is more likely to spread on the drain electrode 6 side than on the gate electrode 7 side, and variation in breakdown voltage is suppressed. Then, from midway of the portion 8a of the PSJ structure extending from the gate electrode 7 side to the drain electrode 6 side, the width D of the portion 8a of the PSJ structure is gradually decreased toward the drain electrode 6 side. Accordingly, the concentration of the two-dimensional electron gas layer is further increased on the drain electrode 6 side, and variation in ON-resistance is suppressed. Thus, it is possible to provide a nitride-based semiconductor device 53 that suppresses variation in ON-resistance while configuring the electric field strength to be approximately uniform to increase the breakdown voltage and reducing ON-resistance further.

### Fifth Embodiment

FIG. 6 is a plan view showing a fifth embodiment of a nitride-based semiconductor device 54 of the disclosure. Although not particularly limited, as shown in the plan view of FIG. 6, the ends on the drain electrode 6 side of the portions 8a of the PSJ structure adjacent in the Y-direction are connected by a connection part 8b of the third nitride-based semiconductor layer 8. The connection part 8b of the third nitride-based semiconductor layer 8 also forms a portion of the PSJ structure. The nitride-based semiconductor device 54 has a structure provided with recesses (holes) 10 that are long in the X-direction of the portion of the PSJ structure of the third nitride-based semiconductor layer 8. Within the range enclosed by the length B of the PSJ structure, multiple recesses (holes) 10 having a length A extending from the drain electrode 6 side to the gate electrode 7 side are provided in a direction (Y-direction in FIG. 6) in which the gate electrode 7 extends.

In addition, within the range of the maximum length Bₘₐₓ of the PSJ structure, the area in which a two-dimensional hole gas layer is formed in the third nitride-based semiconductor layer 8 may be smaller than the area (E × Bₘₐₓ) of a range enclosed and defined with respect to a length (finger length of the gate electrode 7) E of the gate electrode 7 in the direction (Y-direction in FIG. 6) in which the gate electrode 7 extends, or there may be a region where the hole concentration of the two-dimensional hole gas layer is low.

Thus, multiple holes of recesses (holes) 10 having the length A in the X-direction are provided in the third nitride-based semiconductor layer 8. The periphery of the recesses (holes) 10 is surrounded by the portions 8a and 8b of the PSJ structure.

Directly below the recesses (holes) 10, the concentration of the two-dimensional electron gas layer is relatively high, and the ON-resistance of the nitride-based semiconductor device 54 can be reduced. In addition, the end on the drain electrode 6 side of the PSJ structure is a site where electric field concentration occurs relatively easily. By connecting the ends of the portions 8a of the PSJ structure adjacent in the Y-direction with the connection part 8b of the third nitride-based semiconductor layer 8, the electric field concentration at the end on the drain electrode 6 side of the PSJ structure can be mitigated.

Thus, the nitride-based semiconductor device 54 can reduce ON-resistance while configuring the electric field strength to be further approximately uniform to increase the breakdown voltage.

Obviously, in the nitride-based semiconductor devices of the first to fourth embodiments, similar to the nitride-based semiconductor device of the fifth embodiment, the ends of the portions 8a of the PSJ structure adjacent in the Y-direction may also be connected by the connection part 8b of the third nitride-based semiconductor layer 8.

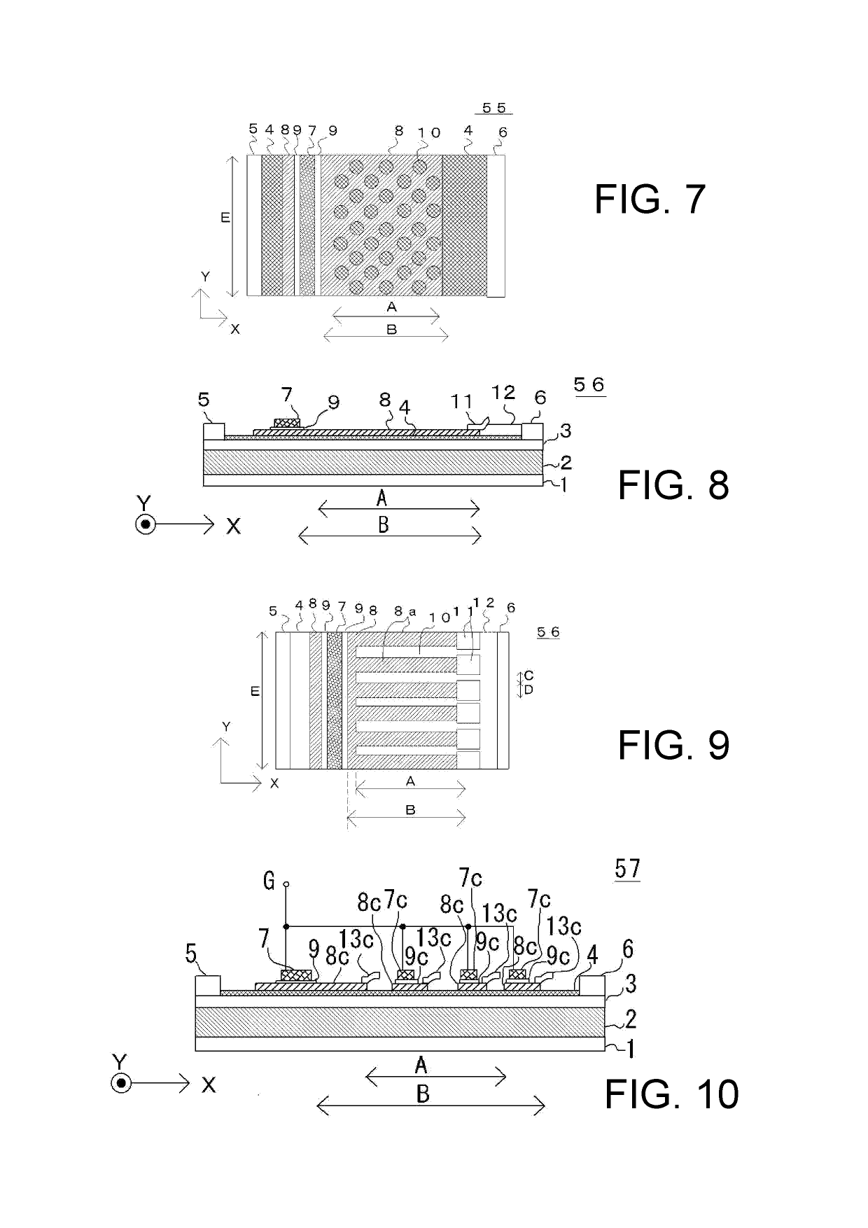

FIG. 7 is a plan view showing a modification example of the fifth embodiment of a nitride-based semiconductor device 55 of the disclosure. Although not particularly limited, as shown in the plan view of FIG. 7, the recesses (holes) 10 may not only be the holes as in FIG. 6, but may also be provided as multiple circular recesses (holes) 10. In addition, as shown in the plan view of FIG. 7, multiple recesses (holes) 10 may be arranged in a staggered manner. In FIG. 7, the recesses (holes) 10 are arranged uniformly in the plane, but more recesses (holes) 10 may also be arranged on the gate electrode 7 side or the drain electrode 6 side in the portion of the PSJ structure.

### Sixth Embodiment

FIG. 8 is a cross-sectional view showing a sixth embodiment of a nitride-based semiconductor device 56 of the disclosure, and FIG. 9 is a plan view showing the sixth embodiment of the nitride-based semiconductor device 56 of the disclosure.

Although not particularly limited, as shown in the cross-sectional view of FIG. 8, a field plate 11 may be provided at the end of the third nitride-based semiconductor layer 8 of the PSJ structure on the drain electrode 6 side. The field plate 11 extends to the drain electrode 6 side beyond the end of the third nitride-based semiconductor layer 8, and is formed on an insulating film 12.

The field plate 11 may also be provided on the lateral surface of the portion 8a of the PSJ structure along the recess (groove) 10, rather than at the end side of the portion 8a of the PSJ structure.

In addition, the field plate 11 may also be provided on the recess (groove) 10. For example, the field plate 11 may be provided on the recess (groove) 10 on the gate electrode 7 side.

The field plate 11 is formed of metal, conductive polysilicon, etc. The field plate 11 may be connected to the third nitride-based semiconductor layer 8.

As shown in the plan view of FIG. 9, the width (width in the Y-direction) of the field plate 11 is wider than the width (width in the Y-direction) of the portion 8a of the PSJ structure opposed thereto, and the field plate 11 may extend to outside of the third nitride-based semiconductor layer 8.

In addition, the field plate 11 may be electrically connected to the gate electrode 7. By providing the field plate 11, electric field concentration at the end of the third nitride-based semiconductor layer 8 on the drain electrode 6 side can be mitigated. In particular, since the recess (groove) 10 extends from the drain electrode 6 side, by providing the field plate 11 at the end of the portion 8a of the PSJ structure on the drain electrode 6 side, electric field concentration on the drain electrode 6 side of the PSJ structure can be further mitigated. In addition, for example, as shown in FIG. 9, by configuring the width (width in the Y-direction) of the field plate 11 to be larger than the width (width in the Y-direction) of the portion 8a of the PSJ structure on the drain electrode 6 side and providing the field plate 11 toward the recess (groove) 10, electric field concentration on the drain electrode 6 side of the PSJ structure can be further mitigated.

Thus, the nitride-based semiconductor device 56 can reduce electron trapping further and reduce the current collapse phenomenon further while suppressing an increase in ON-resistance.

Obviously, in the first to fifth embodiments, similar to the sixth embodiment, the field plate 11 may also be provided.

Within the range enclosed by the maximum length Bₘₐₓ of the PSJ structure, multiple recesses (grooves) 10 having a length A extending from the drain electrode 6 side to the gate electrode 7 side are provided in a direction (Y-direction in FIG. 9) in which the gate electrode 7 extends. In addition, within the range of the maximum length Bₘₐₓ of the PSJ structure, the area in which a two-dimensional hole gas layer is formed in the third nitride-based semiconductor layer 8 may be smaller than the area (E × Bₘₐₓ) of a range enclosed and defined with respect to a length (finger length of the gate electrode 7) E of the gate electrode 7 in the direction (Y-direction in FIG. 9) in which the gate electrode 7 extends, or there may be a region where the hole concentration of the two-dimensional hole gas layer is low.

Thus, the nitride-based semiconductor device 56 can reduce ON-resistance while configuring the electric field strength to be further approximately uniform to increase the breakdown voltage.

### Seventh Embodiment

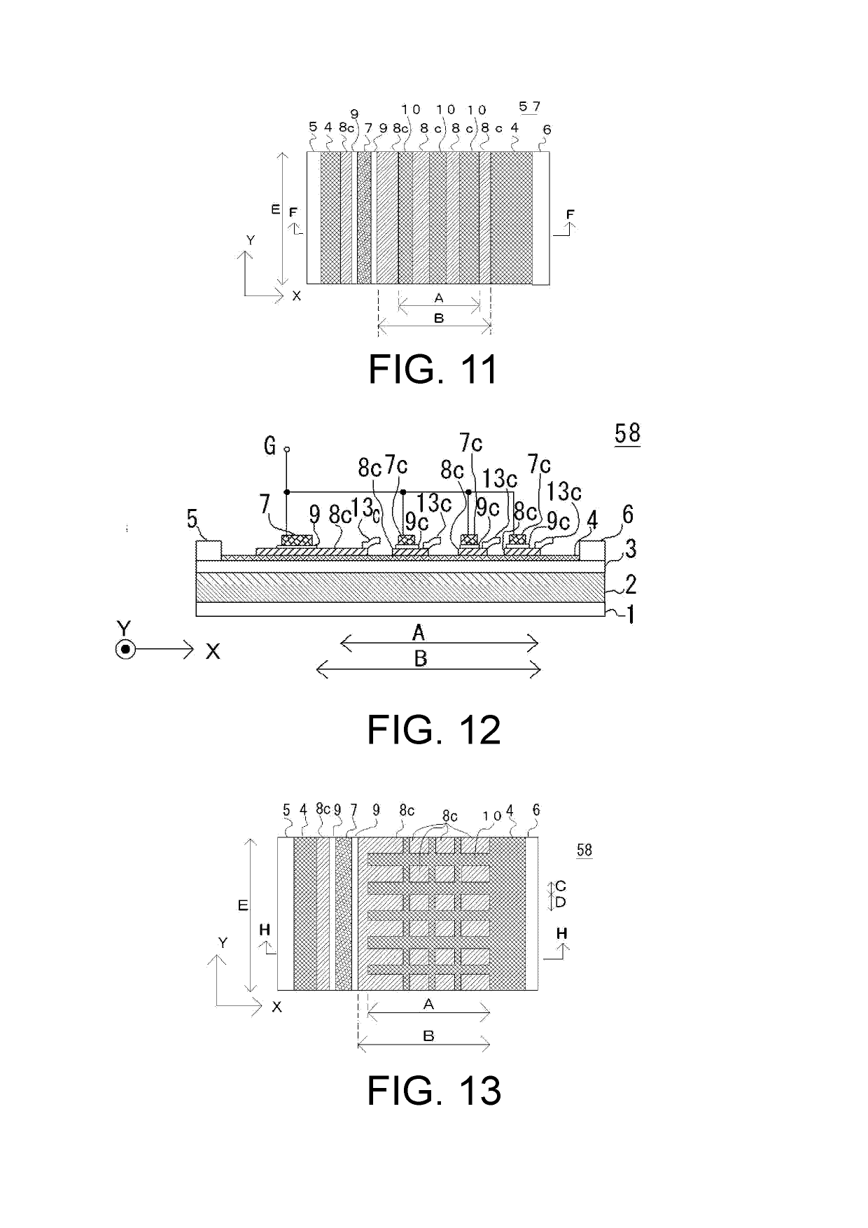

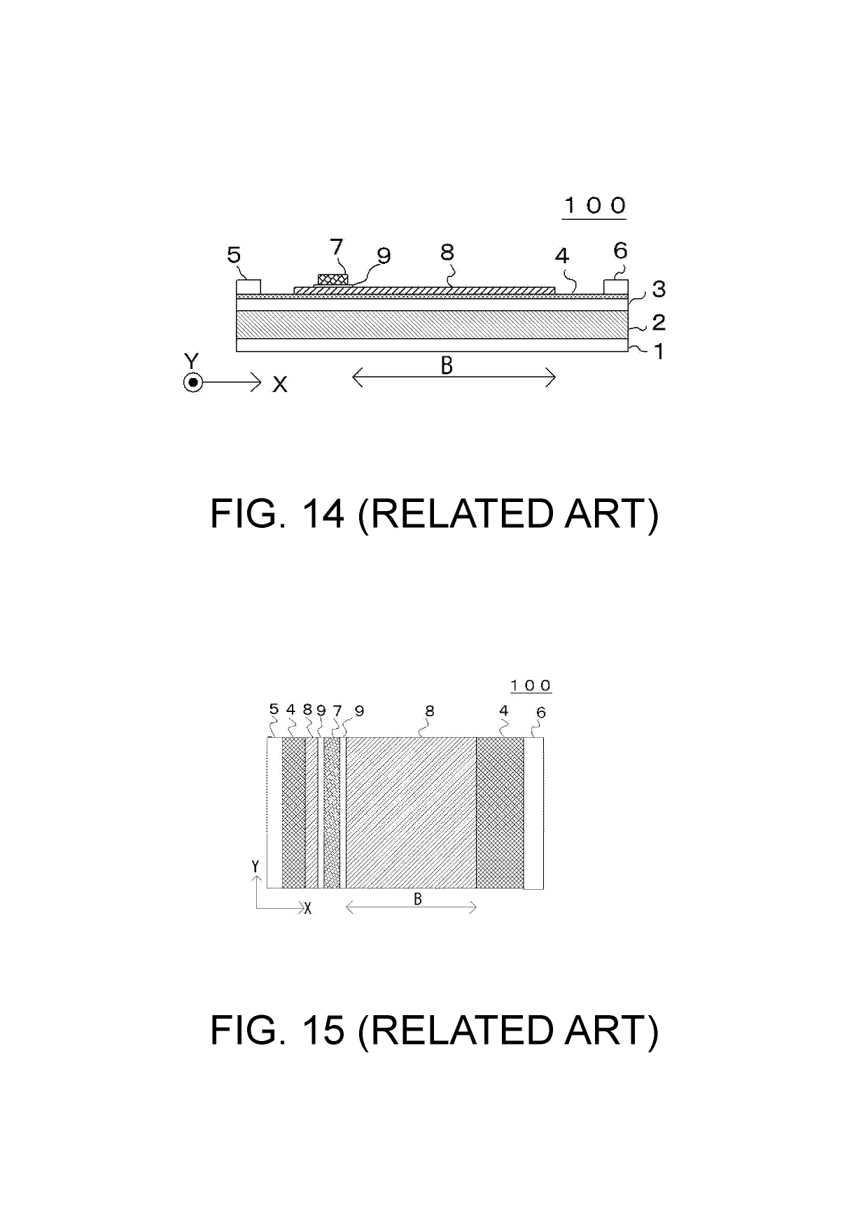

FIG. 10 is a cross-sectional view showing a seventh embodiment of a nitride-based semiconductor device 57 of the disclosure, and is a cross-sectional view taken along F-F in a plan view of FIG. 11. FIG. 11 is a plan view showing the seventh embodiment of the nitride-based semiconductor device 57 of the disclosure. In FIG. 11, a gate electrode 7c, a P-type semiconductor layer 9c, and a field plate 13c are omitted.

Although not particularly limited, as shown in the cross-sectional view of FIG. 10, recesses (grooves) 10 in a direction (Y-direction) in which the gate electrode 7 extends are provided in the PSJ structure of the third nitride-based semiconductor layer 8. For example, the third nitride-based semiconductor layer is divided into multiple portions in the X-direction by the recesses (grooves) 10, and the third nitride-based semiconductor layers 8c that are separated from each other are provided on the second nitride-based semiconductor layer 4. That is, divided PSJ structures are formed on the second nitride-based semiconductor layer 4.

Each of the third nitride-based semiconductor layers 8c is provided with a P-type semiconductor layer 9c and a gate electrode 7c, and each third nitride-based semiconductor layer 8c extends to the drain electrode 6 side beyond the respectively corresponding P-type semiconductor layer 9c. Each gate electrode 7c is electrically connected to the gate electrode 7. Herein, a length B of the PSJ structure of the third nitride-based semiconductor layer 8 extending to the drain electrode 6 side beyond the P-type semiconductor layer 9 in FIG. 1 is approximately the same length as a length B from an end of the third nitride-based semiconductor layer 8c on the drain electrode 6 side at which the gate electrode 7 closest to the source electrode 5 side and the third nitride-based semiconductor layer 8c are connected in FIG. 11, to an end of the third nitride-based semiconductor layer 8c closest to the drain electrode 6 side connected to the gate electrode 7.

Thus, the nitride-based semiconductor device 57 has a structure in which the third nitride-based semiconductor layers 8c provided intermittently on the second nitride-based semiconductor layer 4 are connected to the gate electrode G, and the entire portion of the PSJ structure of the nitride-based semiconductor device 57 is within the range of the length B in FIG. 10 and FIG. 11, with the recesses (grooves) 10 provided within the range of the length A.

As viewed from the gate electrode 7 closest to the source electrode 5 side, from the end on the drain electrode 6 side at which the gate electrode 7 closest to the source electrode 5 side and the third nitride-based semiconductor layer 8c are connected, to the end of the portion of the PSJ structure of the third nitride-based semiconductor layer closest to the drain electrode 6 side connected to the gate electrode 7 (range of the length B), multiple recesses (grooves) 10 extending in the Y-direction of FIG. 11 are provided from the drain electrode 6 side to the gate electrode 7 side (X-direction in FIG. 11). Within the range of the maximum length Bₘₐₓ of the portion of the PSJ structure in the X-direction, the area in which a two-dimensional hole gas layer is formed in the third nitride-based semiconductor layer 8 may be smaller than the area of a range (E × Bₘₐₓ) defined with respect to a length (finger length of the gate electrode 7) E of the gate electrode 7 in the direction (Y-direction in FIG. 11) in which the gate electrode 7 extends, or there may be a region where the hole concentration of the two-dimensional hole gas layer is low.

In addition, in the X-direction, at least one of the multiple third nitride-based semiconductor layers 8c is provided with a field plate 13c at the end of the third nitride-based semiconductor layer 8c on the drain electrode 6 side. In the nitride-based semiconductor device 57 of FIG. 10, the field plate 13c is provided at all of the multiple third nitride-based semiconductor layers 8c.

The field plate 13c is formed of metal, conductive polysilicon, etc. The field plate 13c may be connected to the third nitride-based semiconductor layer 8c. The field plate 13c may extend to the drain electrode 6 side beyond the end of the third nitride-based semiconductor layer 8c.

With the third nitride-based semiconductor layer provided, the concentration of the two-dimensional electron gas layer directly below the third nitride-based semiconductor layer decreases. For example, the third nitride-based semiconductor layer 8 extending to the drain electrode 6 side beyond the P-type semiconductor layer 9 in FIG. 1 is divided into multiple portions, and the P-type semiconductor layers 9c provided on each third nitride-based semiconductor layer are connected to the gate electrode 7. Herein, by extending each third nitride-based semiconductor layer 8c directly below the P-type semiconductor layer 9c to the drain electrode 6 side, each third nitride-based semiconductor layer 8c functions as a PSJ structure. Thus, in the nitride-based semiconductor device 57, the electric field borne by each PSJ structure increases, and the electric field peak from the gate electrode 7 to the drain electrode 6 can be reduced.

In addition, the concentration of the two-dimensional electron gas layer directly below the recess (groove) 10 between the third nitride-based semiconductor layers 8c can be configured to be relatively high.

Based on the above, it is possible to provide a nitride-based semiconductor device 57 that reduces ON-resistance further while configuring the electric field strength to be approximately uniform to increase the breakdown voltage.

In the first to sixth embodiments, similar to the seventh embodiment, the recesses (grooves) 10 may also be provided in the Y-direction. For example, obviously, the third nitride-based semiconductor layer 8 may be divided, the P-type semiconductor layer 9c and the gate electrode 7c may be provided on each of the divided third nitride-based semiconductor layers 8c, and the gate electrodes 7c may be electrically connected to the gate electrode 7.

In addition, in FIG. 10, although the field plate 13c is provided on all the divided third nitride-based semiconductor layers 8c herein, it is also possible that the field plate 13c is not provided on a part of the divided third nitride-based semiconductor layers 8c.

### Eighth Embodiment

FIG. 12 is a cross-sectional view showing an eighth embodiment of a nitride-based semiconductor device 58 of the disclosure, and is a cross-sectional view taken along H-H in a plan view of FIG. 13. FIG. 13 is a plan view showing the eighth embodiment of the nitride-based semiconductor device 58 of the disclosure. In FIG. 13, a gate electrode 7c, a P-type semiconductor layer 9c, and a field plate 13c are omitted.

Although not particularly limited, as shown in the cross-sectional view of FIG. 12, the PSJ structure of the third nitride-based semiconductor layer 8 is provided with recesses (grooves) 10 extending in a direction (Y-direction) in which the gate electrode 7 extends and in a direction (X-direction) from the gate electrode 7 toward the drain electrode 6. For example, the third nitride-based semiconductor layer is divided into multiple portions by grooves provided in the X-direction and the Y-direction of FIG. 13, and the third nitride-based semiconductor layers 8c that are separated from each other are provided on the second nitride-based semiconductor layer 4.

A length B of the PSJ structure of the third nitride-based semiconductor layer 8 extending to the drain electrode 6 side beyond the gate electrode 7 in FIG. 1 is approximately the same length as a length B from an end on the drain electrode 6 side at which the gate electrode 7 and the third nitride-based semiconductor layer 8c are connected to each other, to an end of the third nitride-based semiconductor layer 8c closest to the drain electrode 6 side connected to the gate electrode 7 in FIG. 13.

Each of the third nitride-based semiconductor layers 8c is provided with a P-type semiconductor layer 9c and a gate electrode 7c, and the third nitride-based semiconductor layer 8c extends to the drain electrode 6 side beyond the P-type semiconductor layer 9c. Each gate electrode 7c is electrically connected to the gate electrode 7.

Thus, the nitride-based semiconductor device 58 has a structure in which the third nitride-based semiconductor layers 8c provided intermittently on the second nitride-based semiconductor layer 4 are connected to the gate electrode 7, and the entire portion of the PSJ structure of the nitride-based semiconductor device 58 is within the range of the length B in FIG. 12 and FIG. 13, with the recesses (grooves) 10 provided within the range of the length A.

As viewed from the gate electrode 7 closest to the source electrode 5 side, in the portion (range of the length B) of the PSJ structure of the third nitride-based semiconductor layer 8c that extends to the drain electrode 6 side and is connected to the gate electrode 7, multiple recesses (grooves) 10 extending in the Y-direction in FIG. 13 are provided from the drain electrode 6 side to the gate electrode 7 side (X-direction in FIG. 13). Within the range of the maximum length Bₘₐₓ of the PSJ structure of the third nitride-based semiconductor layer 8c that extends to the drain electrode 6 side and is connected to the gate electrode as viewed from the gate electrode 7 closest to the source electrode 5 side, the area in which a two-dimensional hole gas layer is formed in the third nitride-based semiconductor layer 8 may be smaller than the area (E × Bₘₐₓ) of a range defined with respect to a length (finger length of the gate electrode 7) E of the gate electrode 7 in the direction (Y-direction in FIG. 13) in which the gate electrode 7 extends, or there may be a region where the hole concentration of the two-dimensional hole gas layer is low.

In addition, in the X-direction, at least one of the multiple third nitride-based semiconductor layers 8c is provided with a field plate 13c at the end of the third nitride-based semiconductor layer 8c that extends beyond the P-type semiconductor layer 9c. In the nitride-based semiconductor device 58 of FIG. 12, the field plate 13c is provided at all of the multiple third nitride-based semiconductor layers 8c.

The field plate 13c is formed of metal, conductive polysilicon, etc. The field plate 13c may be connected to the third nitride-based semiconductor layer 8c. The field plate 13c extends to the drain electrode 6 side beyond the end of the third nitride-based semiconductor layer 8c, and may be formed on an insulating film.

With the third nitride-based semiconductor layer provided, the concentration of the two-dimensional electron gas layer directly below the third nitride-based semiconductor layer decreases. Recesses (grooves) 10 are provided in the third nitride-based semiconductor layer 8 of FIG. 1 in the X-direction and the Y-direction. For example, the portion of the PSJ structure of the third nitride-based semiconductor layer extending to the drain electrode 6 side is divided into multiple portions in the X-direction and the Y-direction, a P-type semiconductor layer 9c is provided on each of the divided third nitride-based semiconductor layers 8c, and the P-type semiconductor layer 9c is connected to the gate electrode 7. Herein, the third nitride-based semiconductor layer 8c is extended to the drain electrode 6 side beyond the P-type semiconductor layer 9c. Accordingly, each third nitride-based semiconductor layer 8c functions as a PSJ structure. Thus, in the nitride-based semiconductor device 58, the electric field borne by each PSJ structure increases, and the electric field peak from the gate electrode 7 to the drain electrode 6 can be reduced.

In addition, the concentration of the two-dimensional electron gas layer directly below between the third nitride-based semiconductor layers 8c can be configured to be relatively high.

Based on the above, it is possible to provide a nitride-based semiconductor device 58 that reduces ON-resistance further while configuring the electric field strength to be approximately uniform to increase the breakdown voltage.

In the nitride-based semiconductor devices of the first to sixth embodiments, similar to the nitride-based semiconductor device of the eighth embodiment, the recesses (grooves) 10 may also be provided in the X-direction and the Y-direction. For example, obviously, the third nitride-based semiconductor layer 8 may be divided, a P-type semiconductor layer 9c and a gate electrode 7c may be provided on each of the divided third nitride-based semiconductor layers 8c, and the gate electrode 7c may be electrically connected to the gate electrode 7.

In addition, although the field plate 13c is provided on all the divided third nitride-based semiconductor layers 8c herein, it is also possible that the field plate 13c is not provided on a part of the divided third nitride-based semiconductor layers 8c.

What is claimed is:

1. A nitride-based semiconductor device comprising:
a first nitride-based semiconductor layer having a two-dimensional electron gas layer at an upper part;
a second nitride-based semiconductor layer provided on the first nitride-based semiconductor layer and having a band gap energy larger than a band gap energy of the first nitride-based semiconductor layer;
a third nitride-based semiconductor layer provided on the second nitride-based semiconductor layer, composed of a nitride-based semiconductor material having a band gap energy smaller than the band gap energy of the second nitride-based semiconductor layer, and having a two-dimensional hole gas layer formed in the vicinity of an interface with the second nitride-based semiconductor layer;
a P-type semiconductor layer on the third nitride-based semiconductor layer;
a first main electrode on a high potential side electrically connected to the two-dimensional electron gas layer;
a second main electrode on a low potential side electrically connected to the two-dimensional electron gas layer; and
a control electrode located between the first main electrode and the second main electrode and electrically connected to the P-type semiconductor layer, wherein
as viewed from the control electrode side, the third nitride-based semiconductor layer on the first main electrode side comprises a recess, or comprises a plurality of third nitride-based semiconductor layers intermittently provided on the second nitride-based semiconductor layer and each of the plurality of third nitride-based semiconductor layers is electrically connected to the control electrode.

2. The nitride-based semiconductor device according to claim 1, wherein
in a plan view,
the recess of the third nitride-based semiconductor layer, or the plurality of third nitride-based semiconductor layers intermittently provided on the second nitride-based semiconductor layer are arranged in an extending direction of the control electrode.

3. The nitride-based semiconductor device according to claim 1, wherein
in a plan view,
the recess of the third nitride-based semiconductor layer, or the plurality of third nitride-based semiconductor layers intermittently provided on the second nitride-based semiconductor layer are arranged in a direction from the control electrode to the first main electrode.

4. The nitride-based semiconductor device according to claim 1, wherein
in a plan view,
in a range where a maximum length of the third nitride-based semiconductor layer extending from the control electrode toward the first main electrode side spreads in an extending direction of the control electrode,
a ratio of the recess is higher on the control electrode side than on the first main electrode side.

5. The nitride-based semiconductor device according to claim 1, wherein
in a plan view,
in a range where a maximum length of the third nitride-based semiconductor layer extending from the control electrode toward the first main electrode side spreads in an extending direction of the control electrode,
a ratio of the recess is higher on the first main electrode side than on the control electrode side.

6. The nitride-based semiconductor device according to claim 1, wherein
a width of the third nitride-based semiconductor layer extending from the control electrode toward the first main electrode comprises:
a widening part that becomes wider from the control electrode side toward the first main electrode side; and
a narrowing part that is located closer to the first main electrode side than the widening part and becomes narrower from the control electrode side toward the first main electrode side.

7. The nitride-based semiconductor device according to claim 1, further comprising:
a field plate provided at an end of the third nitride-based semiconductor layer on the first main electrode side.

8. A nitride-based semiconductor device comprising:
a first nitride-based semiconductor layer having a two-dimensional electron gas layer at an upper part;
a second nitride-based semiconductor layer provided on the first nitride-based semiconductor layer and having a band gap energy larger than a band gap energy of the first nitride-based semiconductor layer;
a third nitride-based semiconductor layer provided on the second nitride-based semiconductor layer, composed of a nitride-based semiconductor material having a band gap energy smaller than the band gap energy of the second nitride-based semiconductor layer, and having a first two-dimensional hole gas layer formed in the vicinity of an interface with the second nitride-based semiconductor layer;
a P-type semiconductor layer on the third nitride-based semiconductor layer;
a first main electrode on a high potential side electrically connected to the two-dimensional electron gas layer;
a second main electrode on a low potential side electrically connected to the two-dimensional electron gas layer; and
a control electrode located between the first main electrode and the second main electrode and electrically connected to the P-type semiconductor layer, wherein
in a plan view, in a region formed by extending a length of the third nitride-based semiconductor layer that ranges from an end closest to the first main electrode side to directly below the control electrode, by a length of the control electrode in an extending direction of the control electrode, there is a region where a two-dimensional hole gas is not formed or has a low concentration.

9. The nitride-based semiconductor device according to claim 8, wherein
a width of the third nitride-based semiconductor layer extending from the control electrode toward the first main electrode comprises:
a widening part that becomes wider from the control electrode side toward the first main electrode side; and
a narrowing part that is located closer to the first main electrode side than the widening part and becomes narrower from the control electrode side toward the first main electrode side.

10. The nitride-based semiconductor device according to claim 8, further comprising:
a field plate provided at an end of the third nitride-based semiconductor layer on the first main electrode side.
